(19) United States
(12) Patent Application Publication
(10) Pub. No.: US 2013/0228820 A1
(43) Pub. Date: Sep. 5, 2013

(54) Optoelectronic Semiconductor Component and Method for Producing it

(71) Applicant: Markus Pichlmaier, Regensburg (DE)

(72) Inventor: Markus Pichlmaier, Regensburg (DE)

(73) Assignee: OSRAM OPTO SEMICONDUCTORS GMBH, Regensburg (DE)

(21) Appl. No.: 13/821,665

(22) PCT Filed: Sep. 5, 2011
(86) PCT No.: PCT/EP11/65317

§ 371 Date: May 20, 2013

(30) Foreign Application Priority Data
Sep. 10, 2010 (DE) 10 2010 044 987.3

(51) Int. Cl. H01L 33/64

(52) U.S. Cl. CPC H01L 33/641
USPC 257/99; 438/26

(57) ABSTRACT

An optoelectronic semiconductor component includes a carrier and a semiconductor chip. The semiconductor chip includes an active layer for generating electromagnetic radiation. The carrier includes electrical conductor tracks on a top side for making electrical contact with the semiconductor chip. The semiconductor chip is fixed on the carrier. The carrier contains Si3N4 or molybdenum. A method for producing such a component is furthermore specified.

This patent application is a national phase filing under section 371 of PCT/EP2011/065317, filed Sep. 5, 2011, which claims the priority of German patent application 10 2010 044 987.3, filed Sep. 10, 2010, each of which is incorporated herein by reference in its entirety.

### TECHNICAL FIELD

The present invention relates to an optoelectronic semiconductor component comprising a carrier and a semiconductor chip. The invention furthermore relates to a method for producing such an optoelectronic component.

### BACKGROUND

German Patent Publication No. DE 11 2005 002 419 T5 specifies a housing for an optoelectronic device.

Optoelectronic semiconductor components conventionally comprise a semiconductor chip arranged on an AlN ceramic. The AlN ceramic with applied semiconductor chip is applied, for example, adhesively bonded, on a metal-core circuit board. The AlN ceramic disadvantageously cannot be soldered on the metal-core circuit board on account of the coefficient of thermal expansion. On account of the use of ceramic and metal-core circuit board, however, the thermal resistance of the entire component is impaired. By way of example, in the case of such components, the thermal resistance of the entire component is composed of the thermal resistance of the semiconductor chip, the thermal resistance of a connection layer between semiconductor chip and AlN ceramic, the thermal resistance of the AlN ceramic, the thermal resistance of the adhesive layer between AlN ceramic and metal-core circuit board and the thermal resistance of the metal-core circuit board. The metal-core circuit board comprises Al, for example.

### SUMMARY OF THE INVENTION

Embodiments of the invention specify an optoelectronic semiconductor component which is distinguished by an improved thermal resistance. Further embodiments of the invention specify a shortened and simplified production of such a component.

The invention provides an optoelectronic semiconductor component comprising a carrier and a semiconductor chip, wherein the semiconductor chip comprises an active layer for generating electromagnetic radiation. The carrier comprises electrical conductor tracks on a top side for making electrical contact with the semiconductor chip. The semiconductor chip is fixed on the carrier. The carrier contains a silicon nitride such as Si₃N₄ or molybdenum (Mo) or a molybdenum alloy or consists of one or of a plurality of the materials mentioned or is manufactured from one of said materials. By way of example, the carrier is not a composite carrier.

An optoelectronic component is, in particular, a component which makes it possible to convert electronically generated energies into light emission, or vice versa. By way of example, the optoelectronic component is a radiation-emitting component.

The semiconductor chip has a fixing side, by which the semiconductor chip is arranged on the carrier. In one development, the semiconductor chip is directly fixed on the carrier.

Furthermore, the semiconductor chip has a radiation exit side, which is situated opposite the fixing side and from which the radiation emitted by the semiconductor chip emerges for the most part.

The semiconductor chip is for example a surface emitting chip, for example a light-emitting diode (LED).

The AlN ceramic conventionally used as carrier is replaced in particular by the Si₃N₄ ceramic as carrier or molybdenum circuit board as carrier. As a result of the high modulus of elasticity of Si₃N₄ and molybdenum, the carrier with applied semiconductor chip can be mounted directly externally. The use of an additional metal-core circuit board is advantageously not necessary, with the result that, inter alia, the production process is simplified and shortened.

In this case, the thermal resistance of the component is composed of the thermal resistance of the semiconductor chip, the thermal resistance of the soldering material between a semiconductor chip and carrier and the thermal resistance of the carrier composed of Si₃N₄ or molybdenum. In comparison with conventional components, therefore, the thermal resistance is reduced by the thermal resistance of the AlN ceramic and the adhesive layer between AlN ceramic and metal-core circuit board.

In the present case, the metal-core circuit board conventionally used can therefore be obviated. This advantageously improves the heat resistance, in particular the thermal resistance. On account of the reduced number of component parts used in the component, the production process is additionally shortened and simplified. Furthermore, the component can be externally mounted in a simplified manner.

The semiconductor chip is electrically conductively connected to the carrier and mechanically fixed thereon by means of a connection layer, for instance, an electrically conductive adhesive layer or a soldering layer.

The active layer of the semiconductor chip preferably comprises a pn junction, a double heterostructure, a single quantum well (SQW) structure or a multi quantum well (MQW) structure for generating radiation. In this case, the designation quantum well structure does not exhibit any significance with regard to the dimensionality of the quantization. It therefore encompasses, inter alia, quantum wells, quantum wires and quantum dots and any combination of these structures.

The semiconductor chip, in particular the active layer, contains at least one III/V semiconductor material, for instance a material from the material systems InₓGa_{y}Al_{1-x-y}P, InₓGa_{y}Al_{1-x-y}N or InₓGa_{y}Al_{1-x-y}As, in each case where 0≦x, y≦1 and x+y≦1. III/V semiconductor materials are particularly suitable for generating radiation in the ultraviolet (InₓGa_{y}Al_{1-x-y}N) through the visible (InₓGa_{y}Al_{1-x-y}N, in particular for blue to green radiation, or InₓGa_{y}Al_{1-x-y}P, in particular for yellow to red radiation) to the infrared (InₓGa_{y}Al_{1-x-y}As) spectral range.

In one development, the carrier has fixing elements for externally fixing the component. In particular, direct external fixing of the component to external component parts can thus be made possible. Advantageously, the component can be mounted directly externally on account of the high modulus of elasticity of Si₃N₄ or molybdenum as carrier.

In one development, the fixing elements are perforations of the carrier, such that the component can be fixed externally by means of screws or rivets, for example.

In one development, the perforations of the carrier are arranged in a manner laterally spaced apart from a mounting region of the semiconductor chip. For fixing the component, a screw or a rivet can in each case be led through the perforations, by means of which the component is externally fixed. The perforations can thus have a screw thread, for example. Simplified external fixing of the component for the end consumer, for example, is thus advantageously made possible.

In one development, the semiconductor chip is a thin-film LED. In the context of the application, a thin-film LED is considered to be an LED during whose production the growth substrate, onto which of a semiconductor layer sequence that forms the semiconductor chip was grown epitaxially, for example, has been detached.

In one development, the semiconductor chip has a two-sided contact-connection. In this case, an electrical contact-connection of the chip is led from an underside of the chip via a connection layer to an electrical conductor track of the carrier. By way of example, the semiconductor chip is fixed directly with a contact area on the conductor track, for example, by means of an electrical adhesive layer or a soldering layer. At a top side of the chip situated opposite the underside, the electrical contact-connection of the chip is effected by means of a bonding wire, for example. In this case, the bonding wire is led from the top side of the chip to a further conductor track of the carrier. In this case, the conductor track and the further conductor track of the carrier are arranged in a manner electrically insulated from one another, for example, by means of a spacing or an electrically insulating layer, in order to avoid short circuits.

Alternatively, the semiconductor chip can be a flip-chip. A one-sided electrical contact-connection of the semiconductor chip is effected in this case. The one-sided contact-connection is effected in particular preferably at the underside of the chip. Such flip-chips are known to the person skilled in the art and will therefore not be explained in any greater detail at this juncture.

In one development, the conductor tracks of the carrier contain a metallization. By way of example, the conductor tacks comprise NiPdAu.

In one development, a plurality of semiconductor chips are directly fixed on the carrier. In this case, the semiconductor chips are preferably each fixed by an underside on a respective conductor track of the carrier and electrically conductively connected thereto. By means of a bonding wire, the top sides of the semiconductor chips are preferably electrically conductively connected to a further conductor track of the carrier. By way of example, a respective semiconductor chip is arranged on a separate first conductor track of the carrier, wherein the bonding wire of each semiconductor chip is electrically conductively connected to the conductor track of an adjacent semiconductor chip. A series interconnection of the semiconductor chips is thus effected in this case. The conductor tracks of the carrier subsequently lead to contact areas of the carrier by means of which the entire component can be electrically contact-connected.

In one development, the semiconductor chip or the semiconductor chips is/are soldered on the carrier, for example, by means of an electrically conductive soldering layer.

In a method for producing an optoelectronic semiconductor component comprising a carrier and a semiconductor chip, the following method steps are employed. The carrier contains Si₃N₄ or molybdenum and has electrical conductor tracks on a top side for making electrical contact with the semiconductor chip the semiconductor chip is applied directly on the carrier.

Advantageous developments of the method emerge analogously to the advantageous developments of the component, and vice versa.

The method according to the invention is distinguished, in particular, by a shortened and simplified production process. In particular, a metal-core circuit board conventionally used can be obviated, whereby the conventionally required processing steps concerning the metal-core circuit board are omitted.

In one development, the semiconductor chip is applied on the carrier by means of a soldering method. By way of example, an electrically conductive soldering layer is used in this case.

In one development, a plurality of semiconductor chips are applied directly on the carrier. By way of example, the semiconductor chips are applied directly on the carrier by means of a soldering method. Preferably, a respective semiconductor chip is arranged on a conductor track of the carrier and electrically conductively connected thereto. In this case, the conductor tracks of the individual semiconductor chips are electrically insulated from one another by means of a spacing or an electrically insulating layer. The further electrical contact-connection is effected, for example, by means of a bonding wire from the top side of each semiconductor chip to an adjacent conductor track on which an adjacent semiconductor chip has already been arranged and electrically contact-connected.

In one development, perforations are formed in the carrier. The perforations are advantageously formed in a manner spaced apart laterally from the mounting region of the semiconductor chip or chips.

In one development, for externally fixing the component, screws or rivets are led through the perforations. The perforations have a screw thread, for example, into which a screw is inserted, which makes possible external mounting. By means of the perforations formed in the carrier, therefore, the component can be mounted, for example, screwed, directly by the end consumer, for example. Such a direct mountability is made possible, inter alia, by the high modulus of elasticity of the material of the carrier, that is to say of the Si₃N₄ or molybdenum.

### BRIEF DESCRIPTION OF THE DRAWINGS

Further features, advantages, developments and expediences of the component and the method thereof will become apparent from the following exemplary embodiments explained in conjunction with FIGS. 1 to 5, in which:

FIGS. 1, 2, and 4 each show a schematic cross section of an exemplary embodiment of a component according to the invention;

FIG. 3A shows a schematic plan view of a further exemplary embodiment of a component according to the invention;

FIG. 3B shows a schematic cross section of the exemplary embodiment from FIG. 3A; and

FIG. 5 shows a schematic cross section of an exemplary embodiment of a conventional optoelectronic semiconductor component.

Identical or identically acting constituent parts are in each case provided with the same reference signs. The constituent parts illustrated and also the size relationships of the constituent parts among one another should not be regarded as true to scale.

### DETAILED DESCRIPTION OF ILLUSTRATIVE EMBODIMENTS

FIG. 5 illustrates a conventional optoelectronic semiconductor component 10 comprising a semiconductor chip 1, a carrier 2 and a metal-core circuit board 3. The semiconductor chip 1 is applied on the carrier 2, for example, by means of an adhesive or soldering layer. The carrier 2 is arranged on the metal-core circuit board 3 by means of a fixing layer 5.

The carrier 2 comprises AlN. The metal-core circuit board 3 comprises Al. The fixing layer 5 is a silver layer, for example.

Consequently, conventional optoelectronic components employ a metal-core circuit board 3 and a carrier 2, onto which the semiconductor chip 1 is arranged. In particular, such conventional components comprise three component parts, mainly the chip 1, the carrier 2 and the metal-core circuit board 3.

As a result of this construction comprising three component parts, the thermal resistance of the entire component is composed of the individual thermal resistances of the individual component parts. In particular, the thermal resistance of the component is composed of the thermal resistance of the chip 1, the thermal resistance of the soldering layer 4, the thermal resistance of the carrier 2, the thermal resistance of the fixing layer 5 and the thermal resistance of the metal-core circuit board 3.

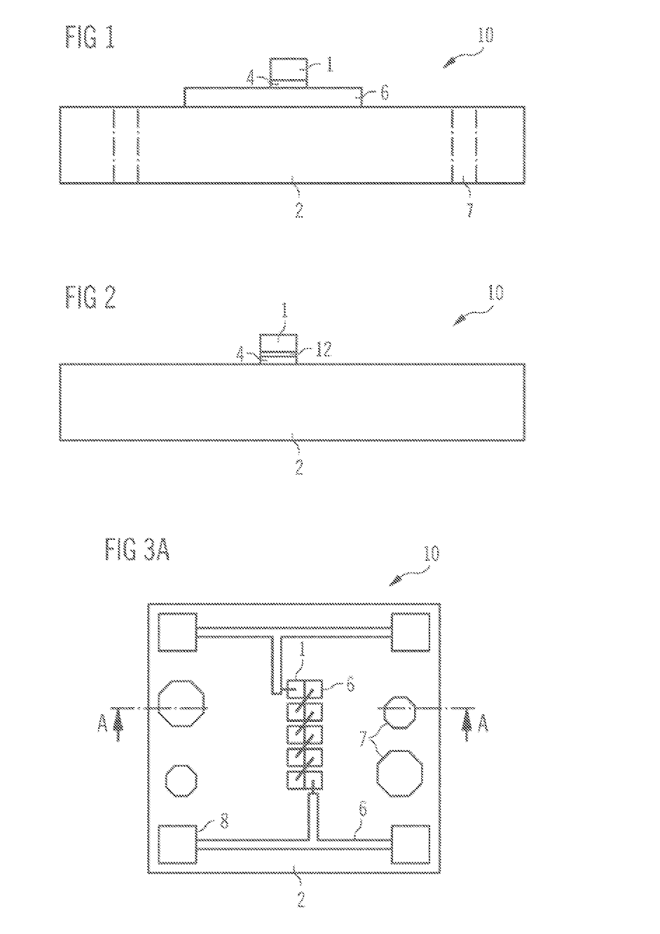

FIG. 1 shows an optoelectronic component according to the invention, comprising a chip 1 and a carrier 2. In contrast to the conventional component, the component 10 according to the invention does not comprise a metal-core circuit board. In particular, the use of a metal-core circuit board is not necessary as a result of which the production process for a component according to the invention is shortened and simplified.

The metal-core circuit board conventionally used can be obviated in particular by virtue of the specific material of the carrier 2. In particular, the carrier 2 comprises Si₃N₄ as material. As a result, the thermal resistance of the component is advantageously improved. In particular, the thermal resistance of the component is composed of the thermal resistance of the chip 1, the thermal resistance of the soldering layer 4 between chip 1 and carrier 2 and the thermal resistance of the carrier 2. The thermal resistance of the component is accordingly reduced by the thermal resistance of the metal-core circuit board and the thermal resistance of the fixing layer that are employed in conventional components.

The component 10 is a surface-mountable component. That means that the component 10 is externally mountable by a mounting side of the carrier 2.

The semiconductor chip 1 is a radiation-emitting chip, in particular an LED.

The semiconductor chip 1 comprises an active layer suitable for generating electromagnetic radiation. The semiconductor chip 1 is embodied in a thin-film design, in particular. The semiconductor chip 1 comprises epitaxially deposited layers that form the chip 1. The layers of the chip 1 are preferably based on a III/V compound semiconductor material.

The semiconductor chip 1 has a radiation exit side, at which the radiation generated in the active layer emerges from the chip 1 for the most part. The radiation exit side of the chip 1 is arranged at the opposite side of the chip relative to the carrier. The chip 1 is arranged with a side situated opposite the radiation exit side on a conductor track 6 of the carrier 2. In particular, the semiconductor chip 1 is directly electrically conductively and mechanically connected to an electrical conductor track 6 of the carrier, for example, by means of the electrically conductive soldering layer 4.

In the exemplary embodiment in FIG. 1, the semiconductor chip 1 is a semiconductor chip having a two-sided contact-connection. The semiconductor chip 1 thus has a first contact area on the opposite side relative to the radiation exit side, said first contact area being electrically conductively connected to the conductor track 6 of the carrier via the soldering layer 4. On the radiation exit side, the semiconductor chip 1 has a further contact area, which is electrically conductively connected to a further conductor track of the carrier 2, for example, by means of a bonding wire (not illustrated). The individual electrical conductor tracks of the carrier 2 are arranged in a manner electrically insulated from one another, for example, by means of a spacing or an electrically insulating layer. The conductor tracks 6 arranged on the carrier 2 thus make possible an electrical contact-connection of the semiconductor chip 1.

The conductor tracks 6 comprise a metallization, in particular NiPdAu.

In particular at least two perforations 7 are arranged in the carrier 2. The perforations 7 can completely penetrate through the carrier. The perforations 7 are not covered by the semiconductor chip 1 and preferably do not serve for making electrical contact with the semiconductor chip 1. The component 10 is directly externally mountable by means of the perforations 7. Depending on the desired application, the component 10 can thus be fixed directly externally by the end consumer.

By way of example, screws or rivet holes can be led through the perforations 7, such that external mounting can be achieved. By way of example, the component 10 can thus be screwed on externally.

The component according to the invention is thus distinguished by simplified external fixing. At the same time, a metal-core circuit board conventionally used can be obviated, whereby the production process is shortened and simplified. Moreover, the thermal resistance of the component is improved as a result of the targeted material selection for the carrier.

The exemplary embodiment in FIG. 2 differs from the exemplary embodiment of FIG. 1 in that the semiconductor chip 1 has a one-sided contact-connection. In particular, the contact-connection of the semiconductor chip 1 is effected on the side situated opposite the radiation exit side.

The semiconductor chip 1 is thus embodied as a so-called flip-chip. In particular, both contact areas of the semiconductor chip 1 are arranged on that side of the chip 1 which faces the carrier 2. The contact areas of the semiconductor chip 1 are arranged in a manner electrically insulated from one another. In this case, the first contact area makes contact with the semiconductor layers of the chip which face the carrier, as viewed from the active layer. The second contact area makes contact with the semiconductor layers of the chip which face away from the carrier, as viewed from the active layer, wherein an insulation layer 12 is arranged between the semiconductor layers and the second contact area in order to avoid short circuits. Such an electrical contact-connection can be made possible, for example, by means of a perforation through the active layer to the layers of the chip which face away from the carrier.

For the rest, the exemplary embodiment of FIG. 2 substantially corresponds to the exemplary embodiment of FIG. 1.

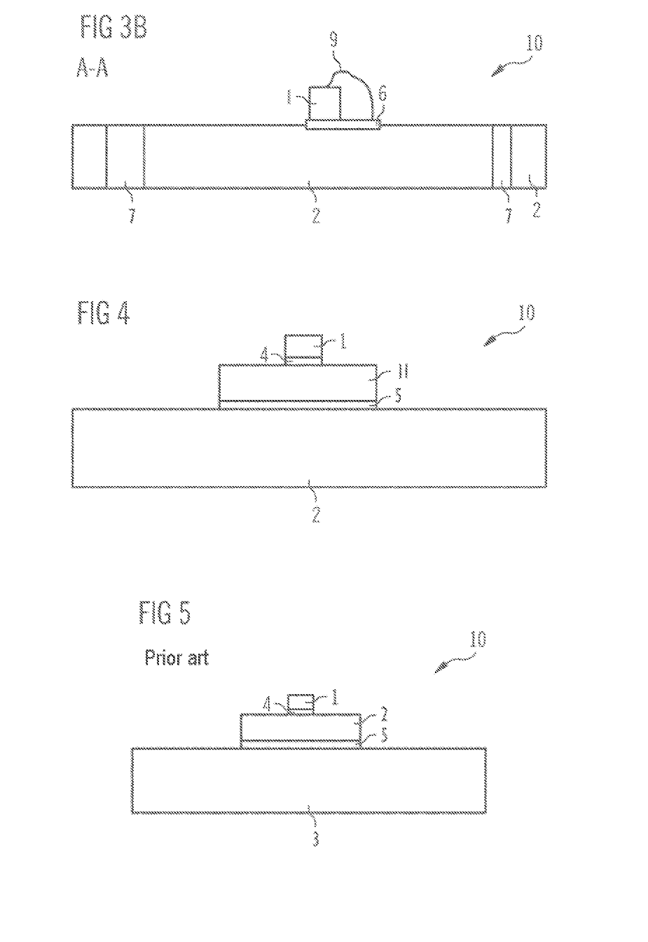

FIGS. 3A and 3B each illustrate a semiconductor component 10 comprising a plurality of semiconductor chips 1.

FIG. 3A shows a plan view of the component 10. In particular, five semiconductor chips 1 are arranged on a carrier 2. A respective semiconductor chip 1 is applied on a conductor track 6 and electrically contact-connected to the respective conductor track 6 by means of a soldering layer. The individual conductor tracks 6 are electrically insulated from one another by means of a spacing.

The semiconductor chips 1 in the exemplary embodiment in FIG. 3A have a two-sided contact-connection. That means that, from a radiation exit side of the semiconductor chips 1, a bonding wire is led from a contact area of the semiconductor chip to a conductor track 6 of the carrier 2. In particular, a respective bonding wire of a semiconductor chip 1 is electrically conductively connected to a conductor track 6 of an adjacent semiconductor chip 1. The semiconductor chips 1 are thus electrically interconnected in series with one another.

Moreover, there are arranged on the carrier 2 conductor tracks 6 on which no semiconductor chip 1 is arranged and which make possible an electrical external contact-connection. These conductor tracks 6 lead to contact areas 8 of the carrier 2. The contact areas 8 are arranged, in particular, in each case at a corner of the carrier 2. A simple electrical contact-connection of the component 10 is made possible as a result.

The carrier 2 has four perforations 7 embodied as screw or rivet holes, for example. By means of the perforations 7, the component 10 is externally mountable, for example, by means of rivets or screws that are led through the perforations 7.

FIG. 3B shows a cross section of the component from FIG. 3A in section through the line A-A. The semiconductor chips 1 are fixed on a conductor track 6 composed of NiPdAu and electrically contact-connected thereto. Moreover, the top-side electrical contact-connection of the chip 1 is effected by means of a bonding wire 9.

In this case, the conductor track 6 is arranged on the carrier 2. The carrier 2 comprises Si₃N₄ as material. Perforations 7 are led through the carrier 2, through which perforations screws can be led, such that the component 10 can be electrically contact-connected. In particular, the component 10 can be electrically and mechanically fixed by means of that side of the carrier which faces away from the semiconductor chip 1.

For the rest, the exemplary embodiment in FIGS. 3A and 3B corresponds to the exemplary embodiment in FIG. 1.

The exemplary embodiment of FIG. 4 differs from the exemplary embodiment of FIG. 1 in that the carrier 2 comprises molybdenum (Mo) instead of Si₃N₄ as material. As a further difference with respect to FIG. 1, the carrier 2 is formed with an NiAu sheathing.

Furthermore, as a difference with respect to FIG. 1, an intermediate component part 11 is arranged between chip 1 and carrier 2. The intermediate component part 11 comprises AN, for example.

The semiconductor chip 1 is thus applied on the intermediate component part 11 by means of a soldering layer 4. The intermediate component part 11 is in turn arranged on the carrier 2 by means of a fixing layer 5. By way of example, the intermediate component part 11 is fixed on the carrier 2 by means of a soldering layer 5.

In contrast to components conventionally produced, no silver layer is employed between intermediate component part 11 and carrier 2. Rather, a soldering layer can be used. The thermal resistance of the component is advantageously improved as a result.

For the rest, the exemplary embodiment in FIG. 4 substantially corresponds to the exemplary embodiment in FIG. 1.

The invention is not restricted to the exemplary embodiments by the description on the basis of said exemplary embodiments, but rather encompasses any novel feature and also any combination of features, which in particular includes any combination of features in the patent claims, even if this feature or this combination itself is not explicitly specified in the patent claims or exemplary embodiments.

1-15. (canceled)

16. An optoelectronic semiconductor component comprising:
a semiconductor chip comprising an active layer configured to generate electromagnetic radiation; and
a carrier comprising electrical conductor tracks on a top side for making electrical contact with the semiconductor chip;
wherein the carrier consists of molybdenum or a molybdenum compound;
wherein the semiconductor chip is directly fixed on the carrier;
wherein the carrier comprises perforations so that the component can be fixed externally by screws or rivets; and
wherein the perforations are not covered by the semiconductor chip and do not serve for making electrical contact with the semiconductor chip.

17. The optoelectronic semiconductor component according to claim 16, wherein the semiconductor chip is a thin-film LED.

18. The optoelectronic semiconductor component according to claim 16, wherein the conductor tracks have a metallization.

19. The optoelectronic semiconductor component according to claim 18, wherein the conductor tracks comprise NiPdAu.

20. The optoelectronic semiconductor component according to claim 16, wherein a plurality of semiconductor chips are fixed directly on the carrier.

21. The optoelectronic semiconductor component according to claim 20, wherein the semiconductor chips are soldered on the carrier.

22. The optoelectronic semiconductor component according to claim 16, wherein the semiconductor chip is soldered on the carrier.

23. The optoelectronic semiconductor component according to claim 22, wherein the semiconductor chip is a flip-chip.

24. The optoelectronic semiconductor component according to claim 16, wherein the semiconductor chip is a flip-chip.

25. The optoelectronic semiconductor component according to claim 16, wherein the carrier consists of molybdenum.

26. The optoelectronic semiconductor component according to claim 16, wherein the carrier consists of a molybdenum compound.

27. A method for producing an optoelectronic component, the method comprising:
providing a carrier that consists of molybdenum or a molybdenum compound and that has electrical conductor tracks on a top side; and
applying a semiconductor chip on the carrier such that the semiconductor chip makes electrical contact with the electrical conductor tracks;
wherein the carrier has perforations so that the component can be fixed externally by screws or rivets, the perforations not being covered by the semiconductor chip and not serving for making electrical contact with the semiconductor chip.

28. The method according to claim 27, wherein applying the semiconductor chip comprises soldering the semiconductor chip to the carrier.

29. The method according to claim 27, wherein applying the semiconductor chip comprises applying a plurality of semiconductor chips on the carrier.

30. The method according to claim 27, further comprising forming the perforations in the carrier.

31. The method according to claim 30, further comprising leading screws or rivets through the perforations.

32. An optoelectronic semiconductor component comprising:
a carrier; and
a semiconductor chip;
wherein the semiconductor chip comprises an active layer configured to generate electromagnetic radiation;
wherein the carrier comprises electrical conductor tracks on a top side for making electrical contact with the semiconductor chip;
wherein the carrier contains Si₃N₄ or molybdenum; and
wherein the semiconductor chip is fixed on the carrier.

33. The optoelectronic semiconductor component according to claim 32, wherein the carrier consists of molybdenum or a molybdenum compound.

34. The optoelectronic semiconductor component according to claim 32, wherein the carrier comprises perforations so that the component can be fixed externally by screws or rivets and wherein the perforations are not covered by the semiconductor chip and do not serve for making electrical contact with the semiconductor chip.
